(19) United States
(12) Patent Application Publication
(10) Pub. No.: US 2013/0157046 A1
(43) Pub. Date: Jun. 20, 2013

(54) PLASTIC ARTICLE AND METHOD FOR MANUFACTURING THE SAME

(71) Applicants: Xu LIU, Shenzhen City (CN); Da-Hua CAO, Shenzhen City (CN)

(72) Inventors: Xu LIU, Shenzhen City (CN); Da-Hua CAO, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/528,253

(22) Filed: Jun. 20, 2012

(30) Foreign Application Priority Data
Dec. 17, 2011 (CN) 201110423698.4

(51) Int. Cl. B32B 15/20; C23C 14/34; B32B 5/00; B82Y 30/00

(52) U.S. Cl. 428/336; 428/457; 204/192.15; 977/755

(57) ABSTRACT

A plastic article includes a plastic substrate and a non-conductive coating formed on the plastic substrate. The non-conductive coating is a Si—Al composite layer. The Si—Al composite layer has a L* value between 70 to 75, an a* value between 0 to 0.5, and a b* value between 0 to 0.5 in the CIE LAB. A method for manufacturing the plastic article is also provided.

### BACKGROUND

1. Technical Field

The exemplary disclosure generally relates to plastic articles and a method for manufacturing the plastic articles.

2. Description of Related Art

Indium and tin are used as evaporation materials to deposit an In—Sn non-conductive layer on plastic articles by vacuum evaporation deposition. The In—Sn non-conductive layer provides the plastic article a high light transmission and a white metallic luster appearance. During deposition of the In—Sn non-conductive layer, the evaporation materials of indium and tin must be isolated from air to prevent the indium and tin from oxidation and becoming conductive. However, the traditional coating equipment for evaporation depositing the In—Sn non-conductive layer cannot always overcome the problem of air isolation during the deposition. Additionally, indium can be quite expensive.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary disclosure. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of one exemplary embodiment of a plastic article.

FIG. 2 is a cross-sectional view of another exemplary embodiment of a plastic article.

FIG. 3 is a schematic view of a vacuum sputtering device for manufacturing the plastic articles shown in FIGS. 1 and 2.

### DETAILED DESCRIPTION

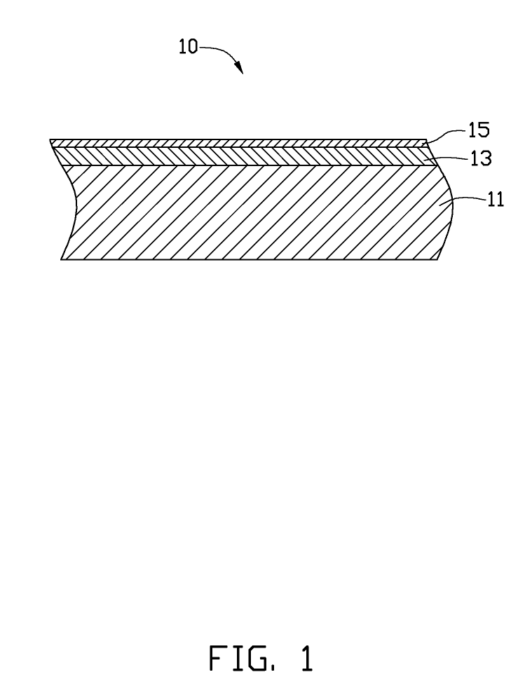

FIG. 1 shows one exemplary embodiment of a plastic article 10. The plastic article 10 includes a plastic substrate 11, a base paint coating 13 directly formed on the substrate 11, and a non-conductive coating 15 directly formed on the base paint coating 13. As used in this disclosure, “directly” means a surface of one layer is in contact with a surface of the other layer.

The base paint coating 13 has a thickness of about 8 μm to about 15 μm. The base paint coating 13 may be an ultraviolet (UV) paint coating or a thermal-curable paint coating. The base paint coating 13 has a smooth surface which enhances the bond between the plastic substrate 11 and the non-conductive coating 15.

The non-conductive coating 15 is a Si—Al composite layer. The non-conductive coating 15 has a thickness of about 20 nm to about 40 nm. The non-conductive coating 15 has a L* value between about 70 to about 75, an a* value between about 0 to about 0.5, and a b* value between about 0 to about 0.5 in the CIE L*a*b* (international commission of illumination, CIE LAB) color space. The non-conductive coating 15 present a white appearance.

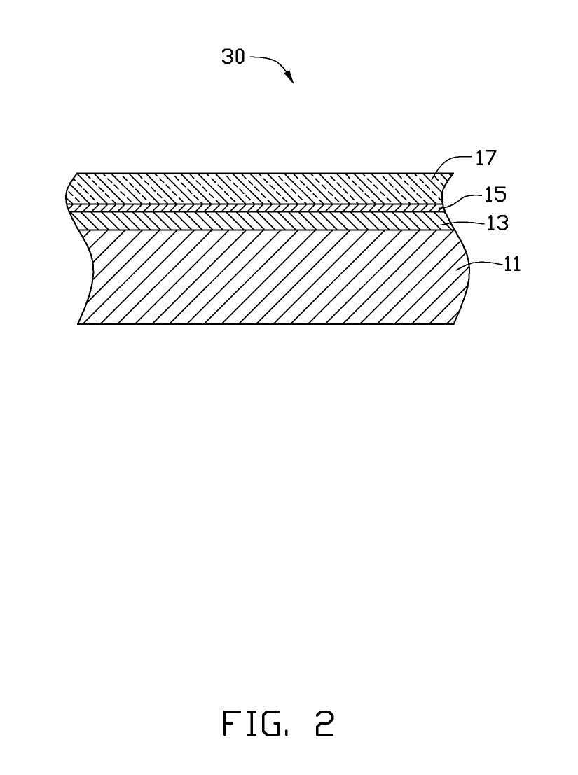

FIG. 2 shows another exemplary embodiment of a plastic article 30. In the exemplary embodiment, the plastic article 30 further includes a top paint coating 17 formed on the non-conductive coating 15. The top paint coating 17 is transparent. The top paint coating 17 has a thickness of about 10 μm to about 20 μm. The top paint coating 17 is a UV paint coating or a thermo-curable paint coating. The top paint coating 17 provides improved wear and corrosion resistances to the plastic article 30.

An exemplary method for manufacturing the plastic article 10 may includes the following steps:

The plastic substrate 11 is provided. The plastic substrate 11 is cleaned using an electrostatic dust removing process.

The base paint coating 13 is directly formed on the plastic substrate 11 by spray painting. UV paint or thermal-curable paint can be used for forming the base paint coating 13. In the exemplary embodiment, UV paint is used. A spray gun is provided to spray the base paint coating 13. The spraying pressure of the spray gun is about 800 Pa to about 1200 Pa. During spraying, the distance between the plastic substrate 11 and the spray gun is about 15 cm to about 25 cm. After spraying, the UV paint is exposed to UV light having a wavelength of about 230 nm to about 400 nm and an energy of between about 1200 mJ/cm² to about 1500 mJ/cm² for about 6 min to about 15 min to solidify. After solidification, the base paint coating 13 has a thickness of about 8 μm to about 15 μm.

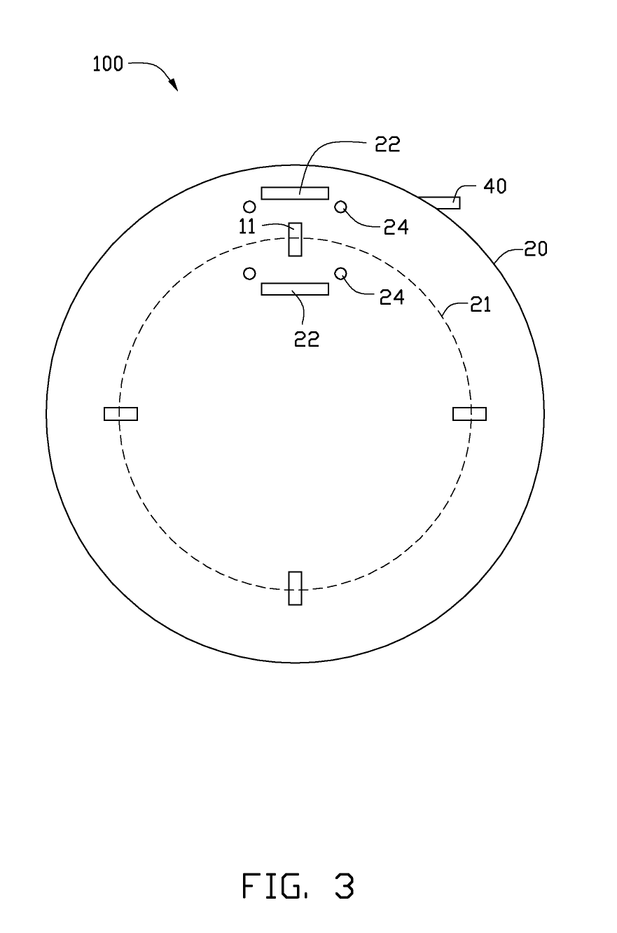

Referring to FIG. 3, a vacuum sputtering device 100 is provided. The vacuum sputtering device 100 includes a chamber 20, and a vacuum pump 40 connected to the chamber 20. The vacuum pump 40 is used to evacuate the chamber 20. The vacuum sputtering device 100 further includes a rotating bracket 21, two targets 22 mounted therein, and a plurality of gas inlets 24. The rotating bracket 21 rotates the substrate 11 in the chamber 20 relative to the targets 22. The two targets 22 face each other, and are located on opposite two sides of the rotating bracket 21. In the exemplary embodiment, the targets 22 are Si—Al composite targets, wherein the mass percentage of the elemental Si is about 70% to about 80%, the mass percentage of the elemental Al is about 20% to about 30%.

A non-conductive coating 15 is directly deposited on the base paint coating 13 by vacuum sputtering. The non-conductive coating layer 15 is a Si—Al composite layer. The plastic substrate 11 is mounted on the rotating bracket 21 in the chamber 20. The chamber 20 is evacuated to about 4×10⁻³ Pa to about 6×10⁻³ Pa. The temperature of the inside of the chamber 20 is room temperature. Argon gas may be used as a working gas and is fed into the chamber 20 at a flow rate from about 160 sccm to about 250 sccm. The targets 22 in the chamber 20 are applied a power between about 6 kW to about 10 kW. Depositing of the non-conductive coating 15 may take about 2 minutes to 6 minutes. The non-conductive coating 15 has a thickness of about 20 nm to about 40 nm.

An exemplary method for manufacturing the plastic article 30 may further include a step of forming a top paint coating 17 on the non-conductive coating 15 by spray painting. The top paint coating 17 is transparent. The paint used for forming the top paint coating 17 can be UV paint or thermal-curable paint, and UV paint was used in the exemplary embodiment. The spraying pressure of the spray gun is about 800 Pa to about 1200 Pa. During spraying, the distance between the plastic substrate 11 and the spray gun is about 15 cm to about 25 cm. After spraying, the UV paint is exposed to UV light having a wavelength of about 230 nm to about 400 nm and an energy of between about 1500 mJ/cm² to about 1800 mJ/cm² for about 6 min to about 15 min to solidify. After solidification, the top paint coating 17 has a thickness of about 10 μm to about 20 μm.

It is to be understood that the base paint coating 13 may be omitted.

It is to be understood that the top paint coating 17 may be omitted.

In the exemplary embodiment, the non-conductive coating 15 formed by vacuum sputtering provides the plastic article 10 and the plastic article 30 a white and metallic luster appearance. Simultaneously, the non-conductive coating 15 has an electromagnetic shielding effectiveness. During the deposition of the non-conductive coating 15, there is no affect on forming the non-conductive coating 15 having the desired color and non-conductivity even if a small amount of oxygen is mixed into the argon gas in the chamber 20. As such, the exemplary process of forming the non-conductive coating 15 has stability and can be repeatedly performed. Additionally, compared to the evaporation material of indium and tin, the Si—Al composite targets can reduce the cost.

### Example 1

Forming the base paint coating 13: the paint used to form the base paint coating 13 was UV paint from PPG industry company (product model: SPR60982). The spraying pressure of the spray gun was about 1000 Pa. The distance between the spray gun and the plastic substrate 11 was about 15 cm. After spraying, the UV paint was exposed to UV light having a wavelength about 315 nm and energy of about 1300 mJ/cm² for about 8 min to solidify. After solidification, the base paint coating 13 has a thickness of about 9 μm.

Depositing the non-conductive layer 15: the chamber 20 was evacuated to about 6×10⁻³ Pa. Argon gas was fed into the chamber 20 at a flow rate from about 180 sccm. A power of about 8 kW was applied to the targets 22 in the chamber 20. Depositing the non-conductive coating 15 took about 3 minutes with all materials and the chamber at room temperature. The non-conductive coating 15 has a thickness of about 25 nm.

The non-conductive coating 15 has a L* value of 72, an a* value of 0.3, and a b* value of 0.2 in the CIE L*a*b* color space. The non-conductive coating 15 is white.

### Example 2

Forming the base paint coating 13: the paint used to form the base paint coating 13 was UV paint from PPG industry company (product model: SPR60982). The spraying pressure of the spray gun was about 1200 Pa. The distance between the spray gun and the plastic substrate 11 was about 20 cm. After spraying, UV paint was exposed to UV light having a wavelength about 315 nm and an energy of about 1400 mJ/cm² for 10 min to solidify. After solidification, the base paint coating 13 has a thickness of about 12 μm.

Depositing the non-conductive layer 15: the chamber 20 was evacuated to about 6×10⁻³ Pa. Argon gas was fed into the chamber 20 at a flow rate from about 200 sccm. A power of about 10 kW was applied to the targets 22 in the chamber 20. Depositing the non-conductive coating 15 took about 2.5 minutes with all materials and the chamber at room temperature. The non-conductive coating 15 has a thickness of about 30 nm.

The non-conductive coating 15 has a L* value of 74, an a* value of 0.2, and a b* value of 0.4 in the CIE L*a*b* color space. The non-conductive coating 15 is white.

Forming the top paint coating 17: the paint used to form the top paint coating 17 was UV paint from PPG industry company (product model: XPC60036) type. The spraying pressure of the spray gun was about 1200 Pa. The distance between the spray gun and the plastic substrate 11 was about 20 cm. After spraying, UV paint was exposed to UV light having a wavelength about 315 nm and an energy of about 1700 mJ/cm² for about 10 min to solidify. After solidification, the base paint coating 13 has a thickness of about 18 μm.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A plastic article, comprising:
a plastic substrate;
a non-conductive coating formed on the plastic substrate, the non-conductive coating being a Si—Al composite coating, the non-conductive coating having a L* value between about 70 to about 75, an a* value between about 0 to about 0.5, and a b* value between about 0 to about 0.5 in the CIE L*a*b* color space.

2. The plastic article as claimed in claim 1, wherein the non-conductive coating has a thickness of about 20 nm to about 40 nm.

3. The plastic article as claimed in claim 2, wherein the plastic article further includes a base paint coating formed between the plastic substrate and the non-conductive coating.

4. The plastic article as claimed in claim 3, wherein the base paint coating has a thickness of about 8 μm to about 15 μm.

5. The plastic article as claimed in claim 3, wherein the plastic article further includes a top paint coating formed on the plastic substrate.

6. The plastic article as claimed in claim 5, wherein the top paint coating has a thickness of about 10 μm to about 20 μm.

7. The plastic article as claimed in claim 6, wherein the top paint coating is transparent.

8. A method for manufacturing a plastic article, comprising:
providing a plastic substrate;
forming a non-conductive coating on the plastic substrate by vacuum sputtering, the non-conductive coating being a Si—Al composite coating, Si—Al composite targets being used as targets to form the Si—Al composite coating, the Si—Al composite coating having a L* value between about 70 to about 75, an a* value between about 0 to about 0.5, and a b* value between about 0 to about 0.5 in the CIE L*a*b* color space.

9. The method for manufacturing a plastic article as claimed in claim 8, wherein in the Si—Al composite targets, the mass percentage of the elemental Si is about 70% to about 80%, the mass percentage of the elemental Al is about 20% to about 30%.

10. The method for manufacturing a plastic article as claimed in claim 9, wherein during deposition of the Si—Al composite coating, a power between about 6 kW to about 10 kW is applied to the targets, argon gas is used as a working gas and have a flow rate from about 160 sccm to about 250 sccm, depositing of the non-conductive coating take about 2 minutes to 6 minutes with all materials and the chamber at room temperature.

11. The method for manufacturing a plastic article as claimed in claim 9, wherein the method further comprise a step of forming a base paint coating on the plastic substrate before depositing the Si—Al composite coating.

12. The method for manufacturing a plastic article as claimed in claim 11, wherein the top paint coating is UV paint coating or a thermal-curable paint coating.

13. The method for manufacturing a plastic article as claimed in claim 12, wherein when the base paint coating is UV paint coating, the base paint coating formed by the following steps: UV paint is sprayed on the plastic substrate, UV paint is exposed to UV light having a wavelength in a range from about 230 nm to about 400 nm and an energy of between about 1200 mJ/cm2 to about 1500 mJ/cm2 for about 6 min to about 15 min.

14. The method for manufacturing a plastic article as claimed in claim 11, wherein the method further comprise a step of forming a top paint coating on the Si—Al composite coating.

15. The method for manufacturing a plastic article as claimed in claim 14, wherein the top paint coating is UV paint coating or a thermal-curable paint coating.

16. The method for manufacturing a plastic article as claimed in claim 15, wherein when the top paint coating is UV paint coating, the top paint coating formed by the following steps: UV paint is sprayed on the plastic substrate, the UV paint is exposed to UV light having a wavelength in a range from about 230 nm to about 400 nm and an energy of between about 1500 mJ/cm2 to about 1800 mJ/cm2 for about 6 min to about 15 min.
